(19) United States
(12) Patent Application Publication
(10) Pub. No.: US 2022/0399736 A1
(43) Pub. Date: Dec. 15, 2022

(54) CHARGING DEVICE AND METHOD FOR CHARGING AN ELECTRICAL ENERGY STORE

(71) Applicant: Robert Bosch GmbH, Stuttgart (DE)

(72) Inventors: Jocelyn Sabatier, Talence Cedex (FR); Olivier Cois, Kernen (DE); Patrick Lanusse, Talence Cedex (FR); Sara Mohajer, Stuttgart (DE)

(21) Appl. No.: 17/765,082

(22) PCT Filed: Aug. 4, 2020
(86) PCT No.: PCT/EP2020/071910

§ 371 Date: Mar. 30, 2022

(30) Foreign Application Priority Data
Sep. 30, 2019 (DE) 10 2019 215 054.3

(51) Int. Cl. H02J 7/00; G01R 31/392; H01M 10/44; H01M 10/48

(52) U.S. Cl. CPC H02J 7/00712; H02J 7/005; H02J 7/0048; G01R 31/392; H01M 10/44; H01M 10/48

(57) ABSTRACT

A charging device (1) and a method for charging an electrical energy store (2), wherein the charging device (1) has an open-loop control unit (12) and a controller (9), and the charging device (1) is configured to charge the electrical energy store (2) to a defined state of charge within a predefined charging period and, in addition, to control a charging current and a secondary-reaction current of the electrical energy store (2).

### BACKGROUND OF THE INVENTION

The present invention relates to a charger and a method for charging an electrical energy store.

US 2014/0091772 A1 discloses a system for dynamically managing heat in a battery pack or an ultracap in an electric vehicle.

WO 2012/0054864 A1 discloses a device and a method for the ultrafast charging of batteries.

US 2013/0179061 A1 discloses a system for managing a power supply system having charging stations for electric vehicles.

The article “Design of a Model-based Fractional-Order Controller for Optimal Charging of Batteries” (IFAC-PapersOnLine, vol. 51, no. 28, pp. 97-102, 2018) discloses a charger for batteries that uses an electrothermal battery aging model.

The article “A Fractional-Order Electro-Thermal Aging Model for Lifetime Enhancement of Lithium-ion Batteries” (IFAC-PapersOnLine, vol. 51, no. 2, pp. 220-225, 2018) discloses a battery model for simulating a voltage response to an input current.

### SUMMARY OF THE INVENTION

The essence of the invention in terms of the charger for an electrical energy store consists in that the charger has an open-loop control unit and a closed-loop control unit, wherein the charger is designed to charge the electrical energy store to a defined state of charge within a preset charging time and, for this purpose, to set a charging current and a side reaction current of the electrical energy store.

The background of the invention consists in that the open-loop control unit and the closed-loop control unit can be operated simultaneously. The open-loop control unit is used to subject the charging current to open-loop control in such a way that the electrical energy store can be charged to the defined state of charge within the preset charging time. At the same time, the closed-loop control unit uses present state parameters of the electrical energy store in order to subject the charging current to closed-loop control in such a way that the ageing of the electrical energy store is minimized.

Advantageously, the charger enables quick matching of the charging current to dynamic state changes of the electrical energy store. As a result, shortening of the charging time or quick-charging of the electrical energy store with reduced ageing is possible.

In accordance with one advantageous configuration, the charger has an evaluation unit, which has at least one terminal for a sensor of the electrical energy store. As a result, the state parameters of the electrical energy store can be evaluated by the evaluation unit and subjected to closed-loop control by the charger. Advantageously, the terminal is suitable for a temperature sensor and/or a voltage sensor.

Advantageously, the evaluation unit is designed to determine at least aging of the electrical energy store by means of a simplified linear electrothermal aging model of the electrical energy store, in particular by means of an aging model approximated by means of a Volterra series. This model makes it possible to determine the aging quickly and with good accuracy so that the charger can react quickly to a state change of the electrical energy store.

It is advantageous in this case if the evaluation unit is connected in signal-conducting fashion to the open-loop control unit and/or to the closed-loop control unit. Thus, the state of charge and/or the state of health can be evaluated by the open-loop control unit and/or the closed-loop control unit, and the charging current can be matched to the present state of charge or the present state of health or can be subjected to closed-loop control.

Advantageously, the open-loop control unit is designed to subject a first charging current and a first side reaction current to open-loop control in such a way that the electrical energy store is charged to the defined state of charge within the preset charging time.

In accordance with a further advantageous configuration, the open-loop control unit has an optimization means, in particular wherein the optimization means is designed to optimize a charging profile, in particular an affine charging profile or a polynomial charging profile, in particular by numerically determining a minimum of a loss function of a parameter of the charging profile, in particular by means of a gradient method. The charging profile advantageously has only a single parameter which can be quickly determined by the optimization means by means of the numerical method, in particular the gradient method.

In this case, it is advantageous if the open-loop control unit has a charge open-loop control means, in particular wherein the charge open-loop control means is designed to subject the first charging current to open-loop control according to an optimized charging profile.

In this case, it is advantageous if the closed-loop control unit is designed to subject a third charging current to closed-loop control in such a way that a second side reaction current of the electrical energy store is minimized. Thus, the ageing of the electrical energy store can be reduced.

Furthermore, it is advantageous if the charger has a summation means, which is arranged between the open-loop control unit and the closed-loop control unit, on one side, and an output terminal of the charger, on the other side, in particular wherein the summation means is designed to add the first charging current or a second charging current from the open-loop control unit and the third charging current from the closed-loop control unit and to generate a fourth charging current as the sum. Thus, when only the first or second charging current is available, this can be used for charging. When a third charging current is unequal to zero, the fourth charging current can be used for charging.

It is advantageous in this case if the charger has a low-pass filter, which is arranged between the open-loop control unit and the summation means, in particular wherein the low-pass filter is designed to smooth the first charging current to give a second charging current.

Advantageously, the charger has a comparison means, which is arranged between the open-loop control unit and the ageing evaluation means, on one side, and the summation means, on the other side, in particular wherein the comparison means is designed to compare the first side reaction current and the second side reaction current. As a result, the side reaction current caused by the open-loop control unit is comparable with the present side reaction current in the electrical energy store, and the ageing of the electrical energy store can be subjected to closed-loop control by the closed-loop control unit.

Advantageously, the comparison means is designed to determine a difference between the first side reaction current and the second side reaction current.

The essence of the invention in terms of the method for charging an electrical energy store, in particular by means of a charger as has been described above or as claimed in one of the claims relating to a charger, consists in that the method has open-loop control method steps and closed-loop control method steps, which run parallel in time, wherein the electrical energy store is charged to a defined state of charge within a preset charging time and, for this purpose, a charging current and a side reaction current of the electrical energy store are set.

The background of the invention consists in that the closed-loop control and the open-loop control run simultaneously. As a result, the charging operation can be matched quickly to dynamic changes in the electrical energy store.

Advantageously, shortening of the charging time or quick-charging of the electrical energy store with reduced ageing is possible.

In accordance with one advantageous configuration, a present state of charge and a present state of health and/or a second side reaction current are determined from sensor data of the electrical energy store, in particular by means of a simplified linear electrothermal aging model of the electrical energy store, in particular which has been approximated by means of a Volterra series. As a result, the present parameters of the electrical energy store can be determined quickly and with low outlay and good accuracy.

It is also advantageous if a charging profile, in particular an affine or polynomial charging profile, is optimized, in particular by numerically determining a minimum of a loss function of a parameter of the charging profile, in particular by means of a gradient method, wherein a first charging current and a first side reaction current are subjected to open-loop control according to an optimized charging profile. In this case, it is advantageous that the charging profile has only a single parameter which can be determined quickly and with good accuracy by means of the numerical method, in particular by means of the gradient method.

It is advantageous in this case if the first side reaction current is compared with the second side reaction current, and a third charging current is generated, in particular wherein the third charging current is equal to zero when the first side reaction current has the same value as the second side reaction current and/or wherein, when the first side reaction current and the second side reaction current have different values, the third charging current is determined in such a way that the ageing of the electrical energy store is minimized, wherein the third charging current and the second charging current are added, and a fourth charging current is generated, in particular wherein the fourth charging current has the same value as the second charging current when the third charging current is equal to zero, wherein the electrical energy store is charged with the second charging current or the fourth charging current, in particular wherein the second charging current is used when a third charging current is not available, and the fourth charging current is used when a third charging current is available. It is advantageous in this case that the second charging current is available as soon as the charging operation is started. The third charging current is available only with a delay since the closed-loop control method steps are more time-consuming than the open-loop control method steps. As soon as the third charging current is available, the fourth charging current can be generated, and the electrical energy store can be charged with the fourth charging current, with the result that the ageing of the electrical energy store can be reduced.

The above configurations and developments can be combined with one another as desired, insofar as this is sensible. Further possible configurations, developments and implementations of the invention also include combinations which have not been explicitly mentioned of features of the invention described above or below in relation to the exemplary embodiments. In particular, in this case a person skilled in the art will also add individual aspects as improvements or additions to the respective basic form of the present invention.

### BRIEF DESCRIPTION OF THE DRAWINGS

In the following section, the invention will be explained on the basis of exemplary embodiments from which further inventive features can result to which the invention is not restricted in terms of its scope, however. The exemplary embodiments are illustrated in the drawings, in which:

FIG. 1 shows a schematic illustration of a method according to the invention for charging an electrical energy store 2 by means of the charger 1 according to the invention,

FIG. 2 shows an affine charging profile for a current Ia as a function of the time t with a total charge Qc, a charging time tch and an initial current Iao,

FIG. 3 shows a polynomial charging profile for a current Ip as a function of the time t with a total charge Qc, a charging time tch and an initial current Ipo, and

FIG. 4 shows a global loss function f of a polynomial charging profile as a function of an optimization parameter d.

### DETAILED DESCRIPTION

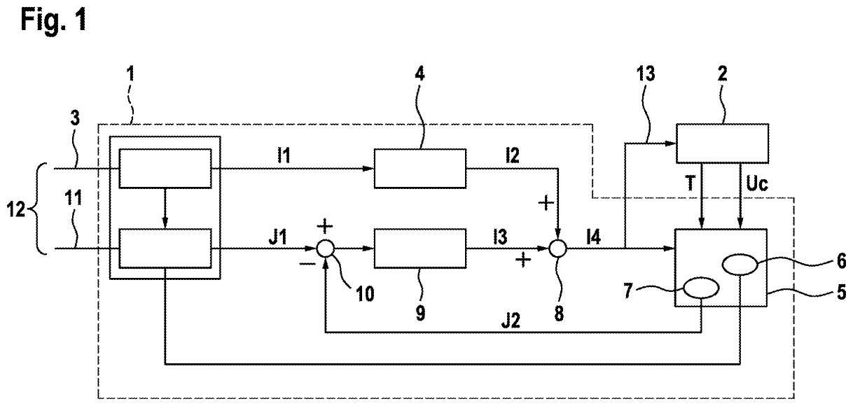

FIG. 1 illustrates the charger 1 according to the invention and the electrical energy store 2 schematically.

The charger 1 has:
an open-loop control unit 12, having an optimization means 3 and a charge open-loop control means 11,
a low-pass filter 4,
an evaluation unit 5, which has a state-of-charge evaluation means 6 and an ageing evaluation means 7,
a summation means 8,
a closed-loop control means 9, and
a comparison means 10.

The evaluation unit 5 is connected in signal-conducting fashion to the electrical energy store 2 and is designed to receive sensor signals from sensors, in particular from a temperature sensor and at least one cell voltage sensor, of the electrical energy store 2. The evaluation unit 5 is designed to evaluate the sensor signals, in particular a temperature T and at least one cell voltage Uc of the electrical energy store 2 and, from this, to determine state parameters of the electrical energy store 2 by means of a fourth charging current I4. For this purpose, the evaluation unit 5 has at least one state-of-charge evaluation means 6 and an ageing evaluation means 7.

The evaluation unit 7 is designed to determine state parameters of the electrical energy store 2 by means of the sensor signals. In this case, the evaluation unit 7 uses a simplified linear electrothermal aging model of the electrical energy store 2 which has been approximated by means of a Volterra series.

The state-of-charge evaluation means 6 is designed to determine a present state of charge of the electrical energy store 2. The state-of-charge evaluation means 6 is connected in signal-conducting fashion to the open-loop control unit 12. The state-of-charge evaluation means 6 is designed to send the present state of charge to the open-loop control unit 12.

The ageing evaluation means 7 is designed to determine a state of health of the electrical energy store 2 and a resultant second side reaction current J2. The ageing evaluation means 7 is connected in signal-conducting fashion to the comparison means 10. The ageing evaluation means 7 is designed to send the second side reaction current J2 to the comparison means 10.

A side reaction current is in this case a current which occurs owing to side reactions in a cell of the electrical energy store 2, such as, for example, dendrite growth or separation of the electrolyte on the anode, owing to the ageing of the cell during charging.

The open-loop control unit 12 is designed to subject a first charging current I1 for charging the electrical energy store 2 and a resultant first side reaction current J1 to open-loop control by means of the state of charge of the electrical energy store 2.

For this purpose, the open-loop control unit 12 has an optimization means 3 and a charge open-loop control means 11.

The optimization means 3 is designed to determine charging parameters of a charging profile starting from the present state of charge of the electrical energy store 2, an available charging time tch and a defined state of charge, which can be reached within the charging time tch, by means of a total charge Qc.

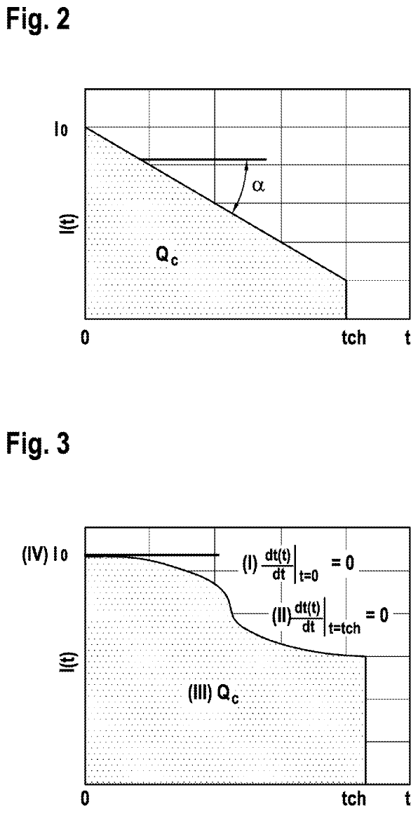

In a first exemplary embodiment, the charging profile is in the form of an affine charging profile Ia(t), as illustrated in FIG. 2. The affine charging profile is linear and has, as a single parameter, a gradient a which is calculated as follows:

$$a = \frac{2 ( {I}_{a 0} {t}_{c h} - Q c )}{{t}_{c h}^{2}} \qquad ( 1 )$$

In a second exemplary embodiment, the charging profile is in the form of a polynomial charging profile Ip(t), as illustrated in FIG. 3. By means of the boundary conditions, whereby the current is constant at the time t=0 and at the time t=tch, that is to say the time derivative of the current is equal to zero at these times, the total charge Qc is predefined and the initial current Ipo is positive and is limited by the cell capacity of the electrical energy store 2, the polynomial charging profile Ip(t) can be represented as follows:

$$Ip ( t ) = \frac{Q c + 0.25 d {t}_{c h}^{4}}{{t}_{c h}} - 1.5 d {t}_{c h} {t}^{2} + d {t}^{3} \qquad ( 2 )$$

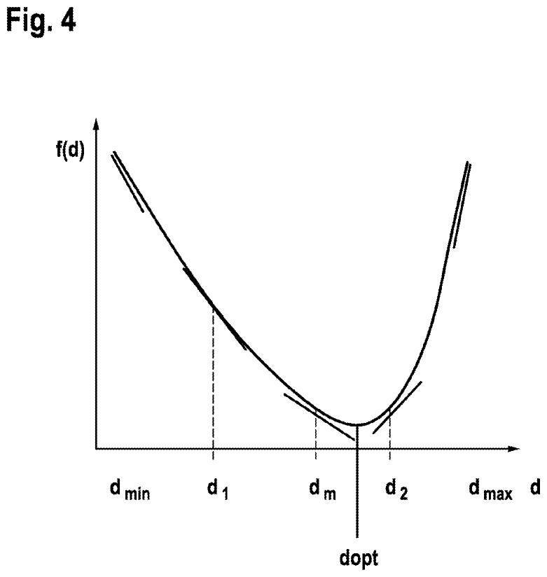

The parameter d of the polynomial charging profile Ip(t) has a loss function f(d) which has a parabolic shape that is still open at the top, as illustrated in FIG. 4. The minimum of the loss function f(d) corresponds to a value for the parameter d which produces a polynomial charging profile Ip(t) that causes minimum aging of the electrical energy store 2.

The optimization means 3 is designed to numerically determine the minimum of the loss function f(d). A gradient method is used for this purpose: the gradient of the loss function f(d) at the outer limit values dmin and dmax of the loss function f(d) and at a mean value dm of the loss function f(d) halfway between the outer limit values dmin and dmax is first of all determined. That range of the parameter d in which the sign of the gradient is reversed and the approximation method is continued with the limit values of this range is then selected. In FIG. 4, this is the range between the mean value dm and the upper limit value dmax, since the gradient is negative for the values dmin and dm and the gradient is positive for the value dmax. As the result, an optimized parameter dopt, for which the loss function f(d) has a minimum, is determined.

The optimization means 3 is designed to output the optimized parameter dopt to the charge open-loop control means 11.

The charge open-loop control means 11 is designed to determine an optimized charging profile Ip(t) for the first current I1 and the resultant first side reaction current J1 by using the optimized parameter dopt and inserting it into formula (2).

The open-loop control unit 12 is electrically conductively connected to the low-pass filter 4. The open-loop control unit is designed to conduct the first charging current I1 to the low-pass filter 4.

The low-pass filter 4 electrically conductively connects the open-loop control unit 12 to the summation means 8. The low-pass filter 4 is designed to smooth the first charging current I1 and to convert it into a second charging current I2 and to conduct the second charging current I2 to the summation means 8.

The open-loop control unit 12 is connected in signal-conducting fashion to the comparison means 10. The open-loop control unit 12 is designed to send the first side reaction current J1 to the comparison means 10.

The comparison means 10 is arranged between the second open-loop control means 11 and the closed-loop control unit 9. The comparison means 10 is arranged between the ageing evaluation means 7 and the closed-loop control unit 9. The comparison means 10 is designed to receive and compare the first side reaction current J1 and the second side reaction current, in particular to form a differential side reaction current, which is the difference between the first side reaction current J1 and the second side reaction current J2. The result of the comparison between the first side reaction current J1 and the second side reaction current J2 is sent to the closed-loop control unit 9.

The closed-loop control unit 9 is arranged between the summation means 8 and the comparison means 10. The closed-loop control unit 9 is designed, on the basis of the present second side reaction current J2 of the electrical energy store, to generate a third charging current I3 for charging the electrical energy store 2, which third charging current effects a side reaction current in the electrical energy store 2 which corresponds to a minimum ageing of the electrical energy store 2. The closed-loop control unit 9 is electrically conductively connected to the summation means 8 and is designed to conduct the third charging current I3 to the summation means 8.

The closed-loop control unit 9 uses a closed-loop control method which is frequency-based and uses fractional differentiation orders as parameters, in particular a CRONE method. In this case, numerical linear models of a nonlinear energy store model are used.

The summation means 8 acts as a node between the low-pass filter 4 and the closed-loop control unit 9, on one side, and the electrical energy store 2 and the evaluation unit 5, on the other side. The summation means 8 is designed to add the second charging current I2 and the third charging current I3 and, from this, to generate a fourth charging current as the sum, which is used for charging the electrical energy store 2. For this purpose, the summation means 8 is electrically conductively connected to the electrical energy store 2. Furthermore, the summation means 8 is connected in signal-conducting fashion to the evaluation unit 5 in order to send the fourth charging current I4 to the evaluation unit 5.

The method according to the invention for charging an electrical energy store 2 has open-loop control method steps and closed-loop control method steps, which run simultaneously or parallel in time.

In a first method step, a present state of charge and a present state of health of the electrical energy store 2, which effects a present second side reaction current J2 in the electrical energy store 2, are determined. In this case, use is made of a simplified linear electrothermal aging model of the electrical energy store 2 which has been approximated by means of a Volterra series.

In open-loop control method steps, a first charging current I1 and a first side reaction current J1 of the electrical energy store 2 are generated using the present state of charge, a defined state of charge to be achieved by means of charging and the available charging time tch.

In a first open-loop control method step, a minimum of a loss function f(d) of a parameter d of a polynomial charging profile Ip(t) is numerically determined. A gradient method is used for this purpose: the gradient of the loss function f(d) at the outer limit values dmin and dmax of the loss function f(d) and at a mean value dm of the loss function f(d) halfway between the outer limit values dmin and dmax is first of all determined. That range of the parameter d in which the sign of the gradient is reversed and the approximation method is continued with the limit values of this range is then selected.

In a second open-loop control method step, an optimized polynomial charging profile Ip(t) is determined for the first current I1 and the resultant first side reaction current J1 by using the optimized parameter dopt and inserting it into formula (2).

In a third open-loop control method step, the first charging current I1 is smoothed to give a second charging current I2 .

In a first closed-loop control method step, the first side reaction current J1 is compared with the second side reaction current J2, and a third charging current I3 is generated. In this case, the third charging current I3 is equal to zero when the first side reaction current J1 has the same value as the second side reaction current J2. When the first side reaction current J1 and the second side reaction current J2 have different values, the third charging current is determined in such a way that the ageing of the electrical energy store 2 is minimized.

In a second closed-loop control method step, the third charging current I3 and the second charging current I2 are added, and a fourth charging current I4 is generated as the sum. In this case, the fourth charging current I4 has the same value as the second charging current I2 when the third charging current I3 is equal to zero.

In a second method step, the electrical energy store 2 is charged with the second charging current I2 or the fourth charging current I4, wherein the second charging current is used when a fourth charging current I4 is not available, and the fourth charging current is used when a fourth charging current I4 is available.

Thereafter, the method is continued with the first method step.

An electrical energy store is in this case understood to mean a rechargeable energy store, in particular having an electrochemical energy store cell and/or an energy store module having at least one electrochemical energy store cell and/or an energy store pack having at least one energy store module. The energy store cell can be in the form of a lithium-based battery cell, in particular lithium-ion battery cell. Alternatively, the energy store cell is in the form of a lithium-polymer battery cell or a nickel-metal hydride battery cell or a lead-acid battery cell or a lithium-air battery cell or a lithium-sulfur battery cell.

1. A charger (1) for an electrical energy store (2), wherein the charger (1) has an open-loop control unit (12) and a closed-loop control unit (9), wherein the charger (1) is configured to charge the electrical energy store (2) to a defined state of charge within a preset charging time and, to set a charging current and a side reaction current of the electrical energy store (2).

2. The charger (1) as claimed in claim 1, wherein the charger (1) has an evaluation unit (5), which has at least one terminal for a sensor of the electrical energy store (2), wherein the evaluation unit (5) is configured to determine at least aging of the electrical energy store (2) by means of a simplified linear electrothermal aging model of the electrical energy store (2).

3. The charger (1) as claimed in claim 2, wherein the evaluation unit (5) is connected in signal-conducting fashion to the open-loop control unit (12) and/or to the closed-loop control unit.

4. The charger (1) as claimed in claim 1, wherein the open-loop control unit (12) is configured to subject a first charging current (I1) and a first side reaction current (J1) to open-loop control in such a way that the electrical energy store (2) is charged to the defined state of charge within the preset charging time.

5. The charger (1) as claimed in claim 1, wherein the open-loop control unit (12) has an optimization means (3) configured to optimize a charging profile by numerically determining a minimum of a loss function of a parameter (d) of the charging profile.

6. The charger (1) as claimed in claim 1, wherein the open-loop control unit (12) has a charge open-loop control means (11) configured to subject the first charging current (I1) to open-loop control according to an optimized charging profile.

7. The charger (1) as claimed in claim 1, wherein the closed-loop control unit (9) is configured to subject a third charging current (I3) to closed-loop control in such a way that a second side reaction current (J2) of the electrical energy store (2) is minimized.

8. The charger (1) as claimed in claim 1, wherein the charger (1) has a summation means (8), which is arranged between the open-loop control unit (12) and the closed-loop control unit (9), on one side, and an output terminal (13) of the charger (1), on the other side, in particular wherein the summation means (8) is configured to add the first charging current (I1) or a second charging current (12) from the open-loop control unit (12) and the third charging current (13) from the closed-loop control unit (9) and to generate a fourth charging current (14).

9. The charger (1) as claimed in claim 8, wherein the charger (1) has a low-pass filter (4), which is arranged between the open-loop control unit (12) and the summation means (8).

10. The charger (1) as claimed in claim 8, wherein the charger (1) has a comparison means (10), which is arranged between the open-loop control unit (12) and the ageing evaluation means (7), on one side, and the summation means (8), on the other side, wherein the comparison means (10) is configured to compare the first side reaction current (J1) and the second side reaction current (J2).

11. A method for charging an electrical energy store (2) by means of a charger (1) having an open-loop control unit (12) and a closed-loop control unit (9), wherein the charger (1) is configured to charge the electrical energy store (2) to a defined state of charge within a preset charging time and to set a charging current and a side reaction current of the electrical energy store (2),
wherein the method comprises an open-loop control steps and a closed-loop control steps, which run simultaneously,
wherein the electrical energy store (2) is charged to a defined state of charge within a preset charging time and a charging current and a side reaction current of the electrical energy store (2) are set.

12. The method (100) as claimed in claim 11, wherein a present state of charge and/or a present state of health and/or a second side reaction current (J2) are determined from sensor data of the electrical energy store (2) means of a simplified linear electrothermal aging model of the electrical energy store (2).

13. The method (100) as claimed in claim 11, wherein a charging profile, in particular an affine or polynomial charging profile, is optimized, in particular by numerically determining a minimum of a loss function of a parameter (d) of the charging profile, in particular by means of a gradient method, wherein a first charging current (I1) and a first side reaction current (J1) are subjected to open-loop control according to an optimized charging profile.

14. The method (100) as claimed in claim 13, wherein the first side reaction current (J1) is compared with the second side reaction current (J2), and a third charging current (I3) is generated, wherein the third charging current (I3) is equal to zero when the first side reaction current (J1) has the same value as the second side reaction current (J2) and/or wherein, when the first side reaction current (J1) and the second side reaction current (J2) have different values, the third charging current (I3) is determined in such a way that the ageing of the electrical energy store (2) is minimized,
wherein the third charging current (I3) and the second charging current (I2) are added, and a fourth charging current (I4) is generated,
wherein the electrical energy store (2) is charged with the fourth charging current (I4).
